(19) United States
(12) Patent Application Publication
(10) Pub. No.: US 2015/0022987 A1
(43) Pub. Date: Jan. 22, 2015

(54) ELECTRONIC DEVICE COMPRISING AN INTEGRATED CIRCUIT CHIP PROVIDED WITH PROJECTING ELECTRICAL CONNECTION PADS

(71) Applicants: STMicroelectronics (Crolles 2) SAS, Crolles (FR); STMicroelectronics (Grenoble 2) SAS, Grenoble (FR)

(72) Inventors: Sebastien Gallois-Garreignot, Grenoble (FR); Jérôme Lopez, Saint-Joseph-De-Riviere (FR); Gil Provent, Coublevie (FR); Caroline Moutin, Sassenage (FR); Vincent Fiori, Sassenage (FR)

(73) Assignees: STMICROELECTRONICS (CROLLES 2) SAS, Crolles (FR); STMICROELECTRONICS (GRENOBLE 2) SAS, Grenoble (FR)

(21) Appl. No.: 14/330,347

(22) Filed: Jul. 14, 2014

(30) Foreign Application Priority Data
Jul. 18, 2013 (FR) 1357071

(51) Int. Cl. H05K 7/02; H05K 1/11

(52) U.S. Cl. CPC H05K 7/02; H05K 1/111; H05K 2201/10439
USPC 361/767

(57) ABSTRACT

An electronic device includes an integrated circuit chip with an insulating passivation layer. An opening in the passivation layer uncovers a first region of an electrical contact. An electrical connection pad is formed to fill the opening by covering the first region and extend in projection in such a way as to cover a second region situated on the passivation layer surrounding the opening. The periphery of at least one of the first and second regions has an elongate or oblong shape. Centers of the opening and the pad are aligned with each other.

### PRIORITY CLAIM

This application claims priority from French Application for Patent No. 1357071 filed Jul. 18, 2013, the disclosure of which is incorporated by reference.

### TECHNICAL FIELD

The present invention relates to the field of electronic devices comprising an integrated circuit chip provided with a projecting electrical connection pad or plurality of pads.

### BACKGROUND

Currently, integrated circuit chips have, in their front face, openings of circular cross section uncovering a number of first circular regions of electrical contacts and the electrical connection pads have parts with circular cross sections that fill said circular openings and cover said first regions and have parts with circular cross sections that extend in projection with respect to said front face and cover, on this front face, a number of second circular regions surrounding said circular openings, and are concentric to said first circular regions.

Known assemblies consist in taking such integrated circuit chips provided with such electrical connection pads and in crushing or soldering or brazing the end parts of the electrical connection pads onto electrical contact regions of electrical connection networks of substrate boards.

When such assemblies are subjected to temperature variations, mechanical stresses, notably shearing and bending stresses, appear in the electrical connection pads due to the fact that the integrated circuit chips and the substrate boards have different thermal expansion coefficients.

Such stresses can generate delamination or debonding, or even breakage, at the level of the first electrical contact regions, of the last layers and possibly of the deep layers or structures of the integrated circuit chips, as well as debonding at the level of the interfaces between the electrical contact regions and the electrical connection pads, making the integrated circuit chips and consequently the assemblies defective.

There is a need in the art to reduce the above drawbacks.

### SUMMARY

An electronic device is proposed that comprises an integrated circuit chip comprising an insulating passivation layer having an opening uncovering a first region of an electrical contact and at least one electrical connection pad filling said opening by covering said first region and extending in projection in such a way as to cover a second region situated on said passivation layer and surrounding said opening, and in which the periphery of at least one of said first and second regions is of elongate or oblong shape, extending in one direction.

The elongate shape can have at least one axis of symmetry.

The shapes of the peripheries of said first and second regions can have superimposed centers.

The peripheries of said first and second regions can be of elongate shapes.

The large dimensions of said elongate shapes can be set out orthogonally.

Said elongate shapes can be elliptical.

Said passivation layer can comprise a first layer having a first opening and a second layer having a second opening larger than said first opening of the first layer, said second region comprising two parts arranged on these first and second layers and separated by said second opening.

### BRIEF DESCRIPTION OF THE DRAWINGS

Some electronic devices 1 will now be described by way of non-limiting examples, illustrated by the drawing in which:

FIG. 1 shows a cut-away of an electronic device;

FIG. 2 shows an assembly of the device in FIG. 1;

FIGS. 3, 5, 7, 9, 11 and 13 show top views of a chip of the device in FIG. 1, in the region of an electrical connection pad, showing particular tie shapes;

FIGS. 4, 6, 8, 10, 12 and 14 show perspective views of the shapes in FIGS. 3, 5, 7, 9, 11, arranged on an electrical connection pad;

FIG. 15 shows a more complete cut-away of the electronic device in FIG. 1;

FIG. 16 shows a cut-away of a variant embodiment of the electronic device in FIG. 1;

FIG. 17 shows a top view of a chip of the device in FIG. 16, in the region of an electrical connection pad, showing particular tie shapes; and

FIG. 18 shows a perspective view of the shapes in FIG. 17, arranged on an electrical connection pad.

### DETAILED DESCRIPTION OF THE DRAWINGS

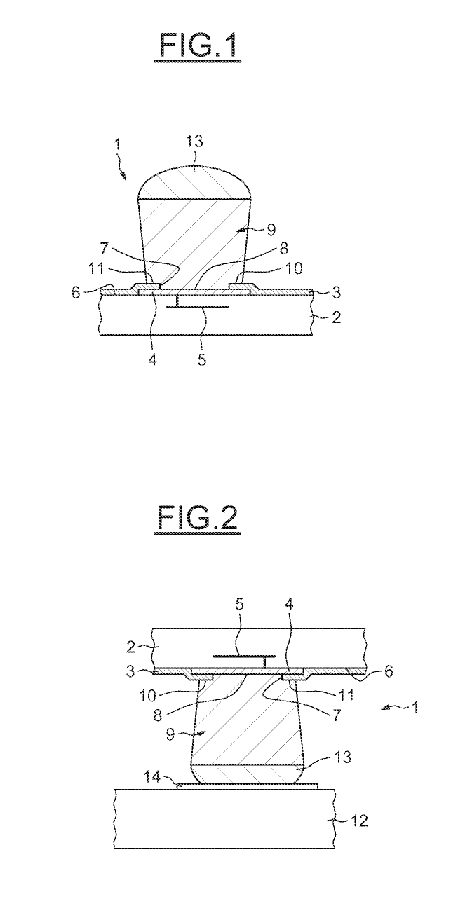

An electronic device 1 illustrated in FIG. 1 comprises an integrated circuit chip 2 which has a front face 3 on which a flat metallic contact 4 (“pad”) of an integrated electrical connection network 5 is arranged.

In a variant embodiment, the integrated circuit chip 2 is provided with an insulating passivation layer 6 which covers the front face 3 and, partly, the metallic contact 4 in such a way that an opening 7 arranged through the passivation layer 6 uncovers a first front region 8 on the metallic contact 4.

The electronic device 1 furthermore comprises an electrical connection pad 9 which fills the opening 7 while covering the first region 8 and which extends in projection with respect to the outer face 10 of the passivation layer 6 while covering a second front region 11 situated on the passivation layer 6 and surrounding the opening 7, the electrical connection pad 9 having a shoulder arranged between these regions 8 and 11. The perimeter of the cross section of the electrical connection pad 9, over its whole height, corresponds substantially to the periphery of the second region 11.

As illustrated in FIG. 2, the electronic device 1 is intended to be mounted on a base board 12 in a position such that the end 13 of the electrical connection pad 9, provided with a soldering material, is flattened and brazed onto a flat electrical contact 14 arranged on a face of the base board 12.

More generally, the electronic device 1 comprises a plurality of electrical connection pads 9 linked to a plurality of metallic contacts 4 of the integrated circuit chip 2, through a plurality of openings 7 arranged in the passivation layer 6, the ends 13 of these electrical connection pads 9, provided with a soldering material, being flattened and brazed onto electrical contacts 14 arranged on a face of the base board 12, in order to electrically link the integrated circuit chip 2 to an electrical connection network supported by the base board 12.

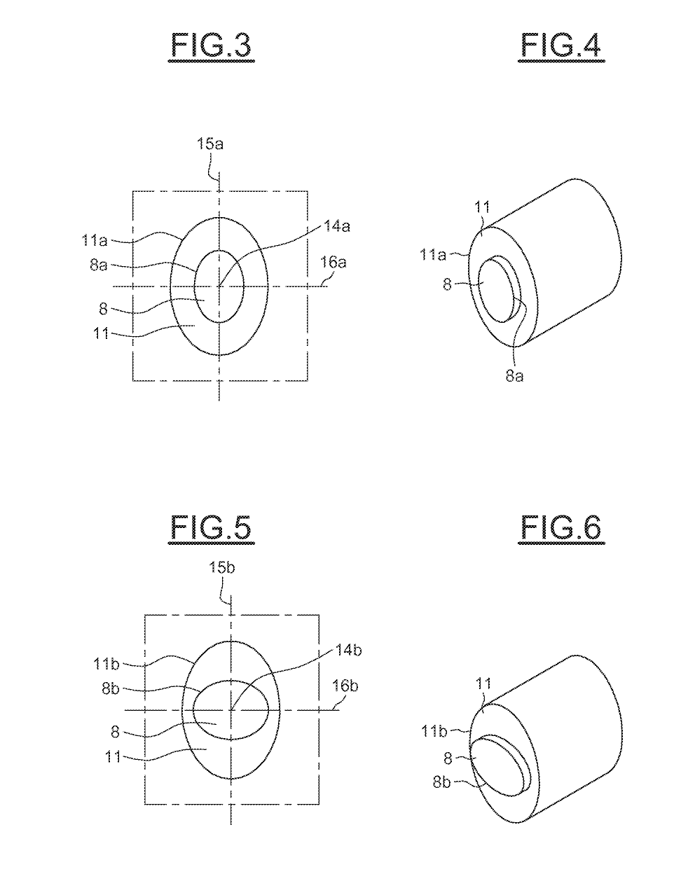

As will result from the examples illustrated in FIGS. 3 to 12, the periphery of at least one of said first and second regions 8 and 11 is of elongate or oblong shape. In the sense of the present description, the expression “of elongate or oblong shape” means that this shape has a maximum large dimension in a principal direction and a maximum small dimension in a secondary direction orthogonal to the principal direction.

As a consequence, the shape of the periphery of one of said first and second regions 8 and 11 can be of elongate or oblong shape and that of the other can be circular, or again the peripheries of the two regions 8 and 11 can be of elongate or oblong shapes.

In a particular disposition, the shapes of the peripheries of the first and second regions 8 and 11 can have superimposed centers.

Thus, in two orthogonal directions containing the large and small dimensions of the elongate shapes, the ratios between, on the one hand, the dimension of the first region and, on the other hand, the dimension of the second region on one side of the first region, or else the sum of the dimensions of the second region on either side of the first region, are different. The result is that, in said directions, the ties or anchorings of the electrical connection pad 9 on the integrated circuit chip 2 are different and react differently under the effect of identical stresses.

In an example illustrated in FIGS. 3 and 4, the periphery 8a (opening 7) of the first region 8 is of elliptical shape and the periphery 11a of the second region 11 is of elliptical shape. Their centers of symmetry 14a are superimposed. Their directions 15a along their large dimensions are superimposed and form axes of symmetry. Their directions 16a along their small dimensions are superimposed and form axes of symmetry.

In another example illustrated in FIGS. 5 and 6, the periphery 8b of the first region 8 is of elliptical shape and the periphery 11b of the second region 11 is also of elliptical shape. Their centers of symmetry 14b and their axis of symmetry are superimposed. The direction 15b along the large dimension of one of the regions 8 and 11 is orthogonal to the direction 16b along the large dimension of the other. The axis or the direction of the large dimension, respectively of the small dimension, of the periphery of one of the said regions 8 and 11 is superimposed to the axis or direction of the periphery of the small dimension, respectively of the large dimension, of the other region.

The disposition of FIGS. 5 and 6 presents the following advantages when forces are applied to the connection pad 9 approximately in the direction of the axis 15b of the large dimension of the periphery 11b of the region 11.

The stresses are distributed in an elongated zone of the region 8, substantially perpendicular to the axis 15b (substantially parallel to axis 16b) and extending along a part of the periphery of the region 8 facing the corresponding extremity of the periphery of the region 11b in the direction 11b. Also and in combination, the stresses are distributed in a large zone of the region 11, extending between this part of the periphery of the region 8 and this corresponding extremity of the periphery of the region 11b in the direction 11b.

This distribution increases the resistance of the attachment or coupling of the pad 9 on the metallic pad 4 and on the passivation layer 6 and reduces the penetration of the stresses towards the interior of the chip 2.

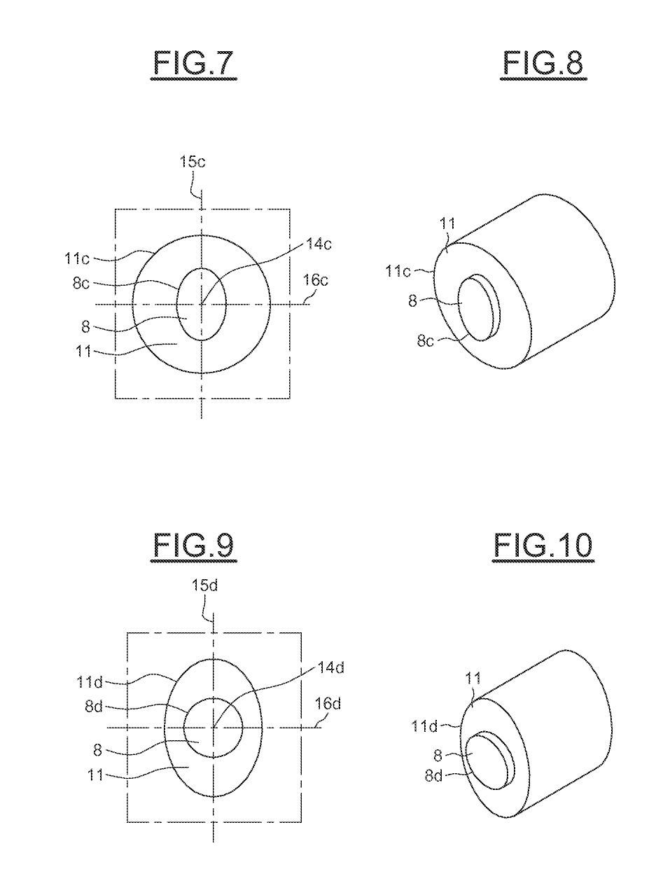

In another example illustrated in FIGS. 7 and 8, the periphery 8c of the first region 8 is of elliptical shape and the periphery 11c of the second region 11 is of circular shape. Their centers of symmetry 14c are superimposed. There is a direction 15c along the large dimension and a direction 16c along the small dimension of the elliptical shape 8c, which form axes of symmetry.

In another example illustrated in FIGS. 9 and 10, the periphery 8d of the first region 8 is of circular shape and the periphery 11d of the second region 11 is of elliptical shape. Their centers of symmetry 14d are superimposed. There is a direction 15d along the large dimension and a direction 16d along the small dimension of the elliptical shape 8d, which form axes of symmetry.

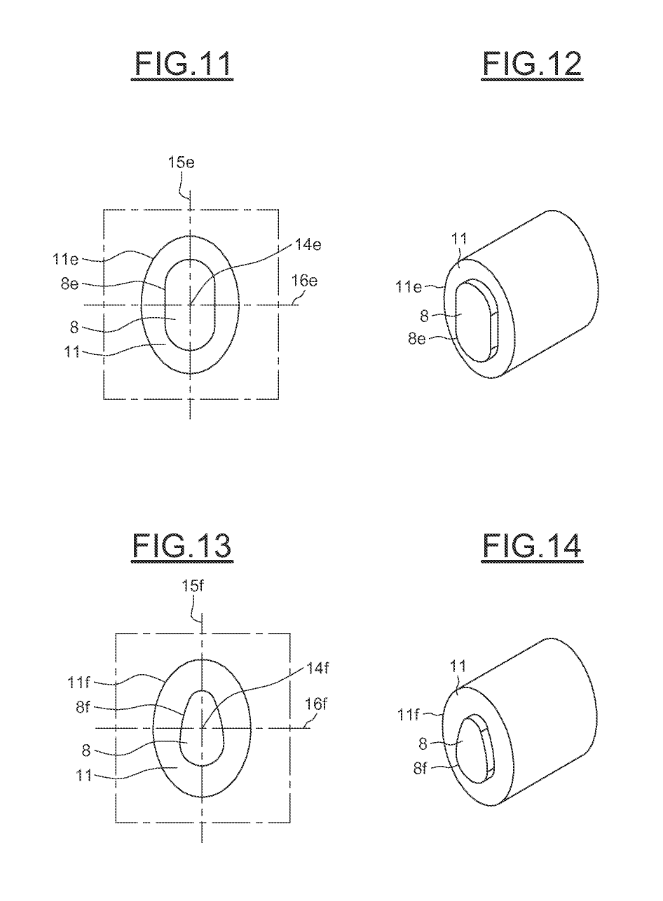

In another example illustrated in FIGS. 11 and 12, the periphery 8e of the first region 8 comprises two parallel sides the ends of which join up by arcs of circles and the periphery 11e of the second region 11 is of elliptical shape. Their centers of symmetry 14e are superimposed. Their directions 15e along their large dimensions are superimposed. Their directions 16e along their small dimensions are superimposed. In a variant embodiment, these shapes could be permuted.

In another example illustrated in FIGS. 13 and 14, the periphery 8f of the first region 8 is of oval shape, for example in the manner of an egg, and the periphery 11f of the second region 11 is of elliptical shape. There is an approximate center 14f. Their directions 16f along their large dimensions are superimposed and form axes of symmetry. In a variant embodiment, these shapes could be permuted.

Considering the above combinations of the shapes of the peripheries of the first and second regions 8 and 11, it can be observed that they are arranged with respect to each other in such a way that its ties on the integrated circuit chip 2 along their two orthogonal principal directions are different These dissymmetric ties are therefore capable of bearing different stresses along these two directions.

In the assembly in FIG. 2, the integrated circuit chip 2 and the base board 12 can be caused to move with respect to each other in a direction of stress by generating stresses in the electrical connection pad 9. This can be the case especially when the ambient temperature varies, the integrated circuit chip 2 and the base board 12 generally not having the same thermal expansion coefficient.

By placing the connection pad 9 in a position such that the direction of greatest resistance of the tie or the anchoring of this latter on the integrated circuit chip 2 coincides with this direction of stress, not only the ties of the connection pad 9 on the regions 8 and 11 but also the internal structures of the integrated circuit chip 2 can be preserved from damage or destruction, by delamination for example.

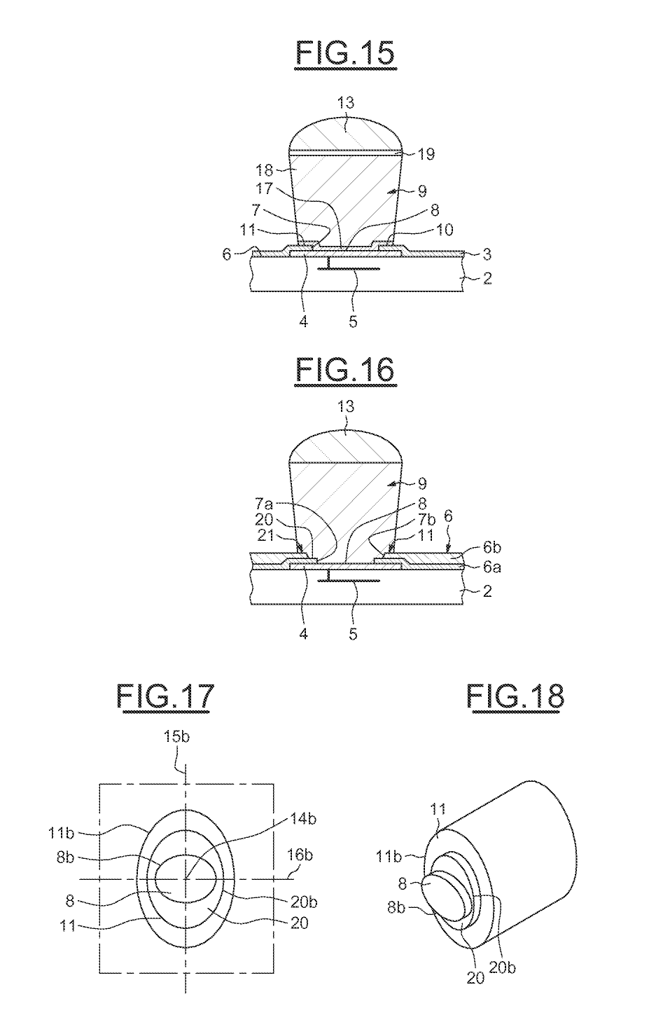

In a variant embodiment illustrated in FIG. 15, the electrical connection pad 9 can comprise a thin conductive tie layer 17 covering the first region 8 and the second region 11, then a thick conductive layer 18 covering the layer 17, then a thin conductive layer 19 covering the layer 18, then the layer of solder 13 covering the layer 19.

By way of example, the passivation layer 6 may be made of silicon nitride, obtained by vapor-phase deposition. The metallic contact 4 of the integrated circuit chip 2 can be made of aluminum. The conductive layer 17 can be obtained by vapor-phase deposition of an underlayer of titanium and an underlayer of copper. By growth or electrodeposition in a passage of a mask, the thick layer 18 can result from a deposition of copper, the layer 19 can result from a deposition of nickel and the layer 13 can result from a deposition on an alloy of tin and silver.

In another embodiment, the passivation layer 6 can comprise a first layer, for example of silicon nitride, and a second layer, for example of polyimide or polybenzoxazole. The opening 7 can be determined either by superimposed edges of these two layers or by an edge of the second layer running alongside the electrical contact 4 with respect to the edge of an opening of the first layer.

In another embodiment illustrated in FIG. 16, the passivation layer 6 comprises a first layer 6a having a first opening 7a delimiting the first region 8, then a second layer 6b having a second opening 7b larger than the opening 7a. The result is that the second tie region 11 of the electrical connection pad 9 comprises a first part 20 extending around the first opening 7a and a second part 21 extending around the second opening 7b. Thus, in the region 11, the electrical connection pad 9 has an additional intermediate shoulder corresponding to the second opening 7b.

The shapes proposed previously (FIGS. 3 to 14) can be attributed to the periphery of the first part 20 of the second region 11 and the various combinations of shapes can be envisaged.

By way of example illustrated in FIGS. 17 and 18, reprising the shapes of FIGS. 5 and 6, the periphery 8b (opening 7a) of the region 8 can be elliptical, the periphery 20b (opening 20) of the first part 20 of the region 11 can be elliptical and the periphery 11b (periphery of the electrical connection pad 9) of the second part 21 of the region 11 can be elliptical. The large dimensions of the elliptical peripheries 11b and 20b are superimposed whereas the small dimension of the elliptical periphery 8b is superimposed on the large dimensions of the elliptical peripheries 11b and 20b.

In a variant embodiment, the large dimensions of the elliptical peripheries 8b and 20b could be superimposed whereas the small dimension of the elliptical periphery 11a could be superimposed on the large dimensions of the elliptical peripheries 8b and 20b.

The present invention is not limited to the examples described above. In particular, the shapes of the peripheries of said tie regions could be different again. They could have the shape of triangles, rectangles, lozenges, or any other polygons exhibiting an elongation along one axis. Many variant embodiments are possible, without departing from the context of the invention.

What is claimed is:

1. An electronic device, comprising:
an integrated circuit chip having an insulating passivation later and including an opening uncovering a first region of an electrical contact;
at least one electrical connection pad filling said opening by covering said first region and extending in projection in such a way as to cover a second region situated on said passivation layer and surrounding said opening;
wherein a periphery of each of said first and second regions is elliptical and presents, according to an orthogonal axis, a large dimension and a small dimension, and
wherein the orthogonal axis or a direction of the large dimension, respectively of the small dimension, of the periphery of one of the first and second regions is superimposed to the orthogonal axis or direction of the small dimension, respectively of the large dimension, of the periphery of the other one of the first and second regions.

2. The device according to claim 1, wherein the peripheries of said first and second regions are of elongate shape.

3. The device according to claim 2, wherein said elongate shapes are elliptical.

4. The device according to claim 1,
wherein said passivation layer comprises a first layer having a first opening and a second layer having a second opening larger than said first opening of the first layer, and
wherein said second region comprises two parts arranged on these first and second layers and separated by said second opening.

5. The device according to claim 1, wherein the shapes of the peripheries of said first and second regions have superimposed centers.

6. An electronic device, comprising:
an integrated circuit chip having an insulating passivation layer and including an opening in the insulating passivation layer which uncovers a first region of an electrical contact; and
at least one electrical connection pad filling said opening by covering said first region and extending in projection in such a way as to cover a second region situated on said passivation layer and surrounding said opening; and
wherein the peripheries of said first and second regions are of elongate shape;
wherein large dimensions of said elongate shapes are set out orthogonally.

7. The device according to claim 1, wherein the elongate shape has at least one axis of symmetry.

8. The device according to claim 1, wherein the shapes of the peripheries of said first and second regions have superimposed centers.

9. The device according to claim 1,
wherein said passivation layer comprises a first layer having a first opening and a second layer having a second opening larger than said first opening of the first layer, and
wherein said second region comprises two parts arranged on these first and second layers and separated by said second opening.

10. An integrated circuit device, comprising:
a passivation layer having an opening formed therein to exposed an underlying conductive contact, said opening having a first peripheral shape, said first peripheral shape having a first center of symmetry;
an electrical connection pad mounted on the passivation layer and in contact with the underlying conductive contact through the opening, said electrical connection pad having a second peripheral shape, said second peripheral shape having a second center of symmetry;
wherein the first and second centers of symmetry are aligned;
wherein both of said first and second peripheral shapes are elongate or oblong; and
wherein a longer dimension of the elongate or oblong first peripheral shape is aligned with a longer dimension of the elongate or oblong second peripheral shape.

11. The device of claim 9, wherein a longer dimension of the elongate or oblong first peripheral shape is perpendicular to a longer dimension of the elongate or oblong second peripheral shape.

12. An integrated circuit device, comprising:
a first passivation layer having a first opening formed therein to exposed an underlying conductive contact, said first opening having a first peripheral shape, said first peripheral shape having a first center of symmetry;
a second passivation layer, on said first passivation layer, having a second opening formed therein to exposed the first opening of the first passivation layer, said second opening having a second peripheral shape, said second peripheral shape having a second center of symmetry;
an electrical connection pad mounted on the first and and second passivation layers and in contact with the underlying conductive contact through the first and second openings, said electrical connection pad having a third peripheral shape, said third peripheral shape having a third center of symmetry;
wherein the first, second and third centers of symmetry are aligned; and
wherein at least one of said first, second and third peripheral shapes is elongate or oblong.

13. The device of claim 12, wherein all of said first, second and third peripheral shapes are elongate or oblong.

14. The device of claim 13, wherein a longer dimension of the elongate or oblong third peripheral shape is aligned with a longer dimension of the elongate or oblong second peripheral shape.

15. The device of claim 13, wherein a longer dimension of the elongate or oblong first peripheral shape is perpendicular to a longer dimension of the elongate or oblong second peripheral shape.
